(19) United States
(12) Patent Application Publication
(10) Pub. No.: US 2022/0247145 A1
(43) Pub. Date: Aug. 4, 2022

(54) LASER LIGHT SOURCE CONTROL SYSTEM AND CONTROL METHOD THEREOF

(71) Applicant: SHENZHEN INTELA LASER TECHNOLOGY CO., LTD., Shenzhen (CN)

(72) Inventors: Fei CHEN, Shenzhen (CN); Xiyue SHI, Shenzhen (CN); Long HUANG, Shenzhen (CN); Xinxing WANG, Shenzhen (CN)

(73) Assignee: SHENZHEN INTELA LASER TECHNOLOGY CO., LTD., Shenzhen (CN)

(21) Appl. No.: 17/616,475

(22) PCT Filed: Mar. 24, 2021
(86) PCT No.: PCT/CN2021/082768

§ 371 Date: Dec. 3, 2021

(30) Foreign Application Priority Data
Mar. 24, 2020 (CN) 202010213633.6
Mar. 24, 2020 (CN) 202020390489.9

(51) Int. Cl. H01S 3/09

(52) U.S. Cl. CPC H01S 3/09; H01S 3/04

(57) ABSTRACT

A laser light source control system includes a master control board, a driver control board, a light source driver board, and an operator control unit. The master control board is provided with a master control unit, a first driver board interface and a laser driver unit. The driver control board is provided with a driver control unit and a constant current board interface. The light source driver board is provided with a light source driver unit. The operator control unit monitors a state of the laser tube and acquire control information of the laser tube. The master control unit outputs the control signal through the laser driver unit. The driver control unit receives the control signal through the first driver board interface, and outputs a conversion signal. The light source driver unit receives the conversion signal through the constant current board interface to drive the laser tube for corresponding display.

### CROSS-REFERENCE TO RELATED APPLICATION

This application is a National Stage Appl. filed under 35 USC 371 of International Patent Application No. PCT/CN2021/082768 with an international filing date of Mar. 24, 2020, designating the United States, now pending, which claims the priority of the Chinese Patent Application No. 202010213633.6 and No. 202020390489.9 filed on Mar. 24, 2020. The contents of which are incorporated herein by reference.

### TECHNICAL FIELD

The present application relates to a light source control system, and more particularly to a laser light source control system and a control method thereof.

### BACKGROUND

The laser light source is an electric light source that uses excited particles to emit light under the action of stimulated radiation, and it is a coherent light source. The laser light source possesses characteristics of good monochromaticity, strong directionality and high brightness, and has been widely used in various fields of industrial and agricultural production, and science and technology. Among them, the large-size projection is one of the applications of the laser light source, in which many laser tubes are needed as the light source. At present, a single control board is used to directly control many laser tubes, while the control board also needs to process other signals, which results in high calculation pressure, high wiring complexity, and limited applicable scenarios.

Therefore, it is necessary to design a new system to reduce the calculation pressure of the total control board and reduce the wiring complexity, and to be applicable for special scenarios.

### SUMMARY

An object of the present application is to overcome the defects in the existing technologies, and provide a laser light source control system and a control method thereof.

In order to achieve the above object, the present application provides the following technical solutions: a laser light source control system, which includes a master control board, a driver control board, a light source driver board, and an operator control unit. The master control board is provided with a master control unit and a laser driver unit. The driver control board is provided with a driver control unit and a constant current board interface. The light source driver board is provided with a light source driver unit.

The driver control board is provided with a first driver board interface, a plurality of the driver control boards are connected through the first driver board interface, the first driver board interface is connected with a second driver board interface, and the master control board is connected to the driver control board through the second driver board interface.

The operator control unit is configured to monitor a state of the laser tube and acquire control information of the laser tube. The master control unit is configured to output a control signal through the laser driver unit.

The driver control unit is configured to receive the control signal through the first driver board interface, and output a conversion signal after digital-to-analog or analog-to-digital conversion is performed on the control signal;

The light source driver unit is configured to receive the conversion signal through the constant current board interface to drive the laser tube to perform corresponding display.

In another embodiment, the master control board is further provided with an interface unit, the master control unit is configured to acquire control information of the laser tube through the interface unit, and generate the control signal according to the control information of the laser tube. The interface unit is in communication with the operator control unit, and the operator control unit is configured to monitor the state of the laser tube and transmit the control information of the laser tube.

In another embodiment, the first driver board interface and the second driver board interface are connected in a tree-type connection, a star-type connection or a chain-type connection.

In another embodiment, the operator control unit includes a touch module, a wireless module, and a touch interface, the touch interface is connected to the interface unit, the touch module is connected to the touch interface, and the wireless module is connected with the master control unit.

In another embodiment, the laser driver unit is also connected with a control board interface, the control board interface is connected with a temperature control device. The temperature control device is connected to the laser driver unit through the control board interface, and is configured to acquire temperature information of each laser tube through the laser driver unit. When the temperature of the laser tube exceeds a threshold, the laser tube is controlled to stop working.

In another embodiment, the temperature control device is also connected to the second driver board interface, and the temperature control device communicates with the driver control unit through the second driver board interface.

In another embodiment, a cooling control unit is provided on the master control board, and a cooling unit is connected to the cooling control unit.

In another embodiment, a power connection unit connected with the master control unit is provided on the master control board, and a power supply unit is connected to the power connection unit. The power supply unit includes a main power supply module and an auxiliary power supply module, where the main power supply module and the auxiliary power supply module are respectively connected to the power connection unit.

In another embodiment, a sensor connection unit is provided on the master control board, and a sensor is provided on the sensor connection unit, where the sensor includes a color sensor.

The present application also provides a control method of the laser light source control system, which includes: inputting, by an operator control unit, information relevant to a laser tube; receiving, by a master control unit, the information relevant to the laser tube through an interface unit, and outputting a control signal through an laser driver unit; receiving, by a driver control unit, the control signal through a driver board interface, and outputting, a conversion signal after performing digital-to-analog or analog-to-digital conversion on the control signal; and receiving, by a light source driver unit, the conversion signal through a constant current board interface to drive the laser tube to perform corresponding display.

Compared with the existing technologies, the present application has the following beneficial effects: it is provided a master control board, a driver control board, a light source driver board, and an operator control unit. The master control board is provided with a master control unit for controlling components other than analog-to-digital (AD) or digital-to-analogy (DA) conversion of signals and a driving current that drives the laser tube. The driver control unit in the driver control board is configured for controlling the AD or DA conversion, and transmitting information of the drive current to the master control unit of the master control board. The light source driver unit of the light source driver board is configured to generate the driving current that drives the laser tube. Such that the calculation pressure of the master control board and the wiring complexity are reduced, which is applicable for special scenarios.

The present application will be further described below in conjunction with the drawings and specific embodiments.

### BRIEF DESCRIPTION OF THE DRAWINGS

In order to illustrate the technical solutions in the embodiments of the present application more clearly, the drawings that need to be used in the description of the embodiments or the existing technologies will be briefly described herein below. Obviously, the drawings in the following description are merely some embodiments of the present application, and for those of ordinary skill in the art can obtain other drawings on the basis of these drawings without creative labor.

FIG. 1 is a schematic structural diagram of a laser light source control system provided by a specific embodiment of the present application; and

FIG. 2 is a schematic diagram of the structure of a light source driver board shown in FIG. 1.

### DETAILED DESCRIPTION OF THE EMBODIMENTS

In order to make the objects, technical solutions and advantages of the present application more comprehensible, the present application will be further described in detail below with reference to the accompanying drawings and specific embodiments.

The technical solutions in the embodiments of the present application will be clearly and completely described below in conjunction with the accompanying drawings in the embodiments of the present application. Obviously, the described embodiments are merely some embodiments of the present application, rather than all the embodiments. Based on the embodiments of the present application, all other embodiments obtained by those skilled in the art without creative work shall fall within the protection scope of the present application.

In the description of the present application, it should be understood that the terms “center,” “longitudinal,” “transverse,” “length,” “width,” “thickness,” “upper,” “lower,” “front,” “back,” “left,” “right,” “vertical,” “horizontal,” “top,” “bottom,” “inner,” “outer,” “clockwise,” “counterclockwise” and other terms indicating direction or position relationship are based on the orientation or position relationship shown in the drawings, which are merely used for the convenience of describing the present application and simplifying the description, rather than indicating or implying that the device or element referred to must have a specific orientation, be constructed and operated in a specific orientation, it thus cannot be understood as a limitation to the present application.

In addition, the terms “first” and “second” are only used for descriptive purposes, and cannot be understood as indicating or implying relative importance or implicitly indicating the number of indicated technical features. Thus, the features defined with “first” and “second” may explicitly or implicitly include one or more of these features. In the description of the present application, “a/the plurality of” means two or more, unless otherwise specifically defined.

In the present application, unless otherwise clearly specified and limited, the terms “installed/mounted,” “in connection with,” “connected/coupled,” “fixed” and other terms should be understood in a broad sense. For example, they may be connected or detachably connected or integrated; it may be a mechanical connection or an electrical connection; it may be directly connected or indirectly connected through an intermediate medium, and it may be an internal communication of two elements or an interaction relationship between two elements. For those of ordinary skill in the art, the specific meaning of the above-mentioned terms in the present application can be understood according to specific circumstances.

In the present application, unless otherwise clearly specified and defined, a first feature is “above/over/on top of” or “below/under/at the bottom of” a second feature may include a direct contact between the first and second features, or may include that the first and second features do not come into a direct contact but through other features between them. Moreover, the first feature is “above,” “over” and “on top of” the second feature may include that the first feature is directly above or obliquely above the second feature, or it simply means that the level of the first feature is higher than that of the second feature. The first feature is “below,” “under” and “at the bottom of” the second feature may include the first feature directly is below or obliquely below the second feature, or it simply means that the level of the first feature is lower than the second feature.

In the present application, descriptions with reference to the terms “an/one embodiment,” “some embodiments,” “examples,” “specific examples,” or “some examples” etc. mean specific features, structure, materials or characteristics described in conjunction with the embodiment or example are included in at least one embodiment or example of the present application. In the present application, the schematic representation of the above-mentioned terms should not be understood as necessarily referring to the same embodiment or example. Moreover, the described specific features, structures, materials or characteristics can be combined in any one or more embodiments or examples in a suitable manner. In addition, those skilled in the art can combine different embodiments or examples described in the present application.

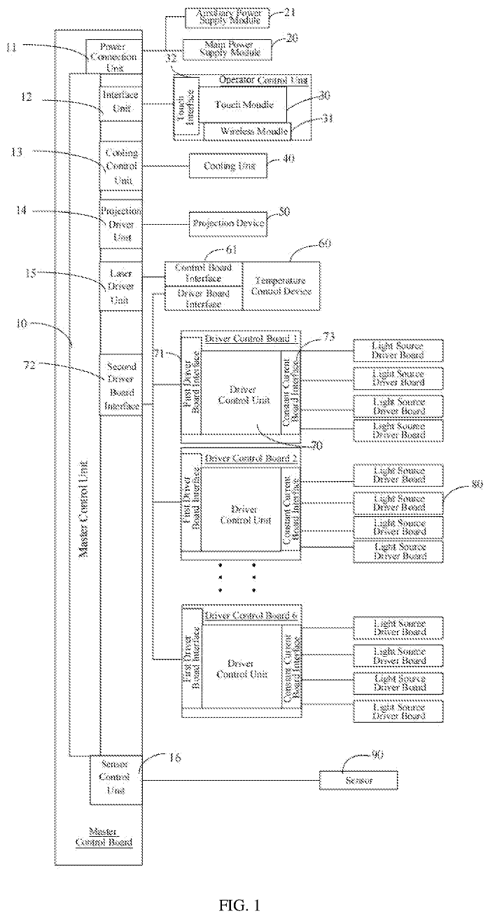

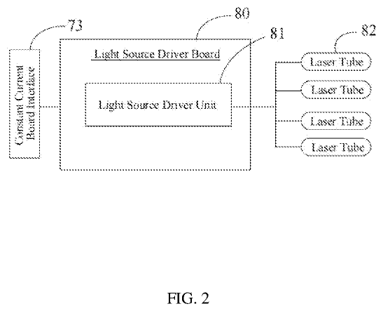

Referring to FIGS. 1 to 2 showing a specific embodiment, in this embodiment it is provided a laser light source control system which can be used in a process of controlling a large number of laser tubes 82.

Referring to FIG. 1, the above-mentioned laser light source control system includes a master control board, a driver control board, a light source driver board 80, and an operator control unit. The master control board is provided with a master control unit 10, an interface unit 12 and a laser driver unit 15. The driver control board is provided with a driver control unit 70, a first driver board interface 71 and a constant current board interface 73. The light source driver board 80 is provided with a light source driver unit 81 (not shown in FIG. 1). The interface unit 12 is in connection with the operator control unit. The interface unit 12 and the laser driver unit 15 are respectively connected to the master control unit 10. The first driver board interface 71 and the constant current board interface 73 are respectively connected to the driver control unit 70. The laser driver unit 15 is connected to the first driver board interface 71. Specifically, with reference to FIG. 2, the light source driver unit 81 is connected with the constant current board interface 73, and the light source driver unit 81 is connected with a laser tube 82. The master control unit 10 of the master control board is responsible for controlling other components, and the driver control unit 70 in the driver control board is responsible for AD or DA conversion, and transmits information of a driving current to the master control unit 10 of the master control board, thereby achieving a control and feedback, the use of a plurality of control boards for controlling can reduce the calculation pressure of the master control board and reduce the complexity of wiring. In addition, the light source driver unit 81 in the above-mentioned light source driver board 80 is used to generate the driving current for driving the laser tube 82. In this way, a working state of the laser tube 82 is controlled, such as lighting, extinguishing, and light output intensity of the laser tube 82. It should be noted that one light source can be used to drive one laser tube 82 or multiple laser tubes 82, and the actual number of laser tubes 82 to be driven can be selected according to actual needs.

The driver control board is provided with a first driver board interface 71, a plurality of the driver control boards are connected through the first driver board interface 71, and the first driver board interface 71 is connected with a second driver board interface 72. The master control board is connected to the driver control board through the second driver board interface 72. Among them, the first driver board interface 71 is a driver board interface on each driver control board; the second driver board interface 72 is a driver board interface connected to the master control board.

Specifically, the operator control unit is configured to monitor the state of the laser tube 82 and acquire control information of the laser tube 82. The master control unit 10 is configured to output a control signal through the laser driver unit. The driver control unit 70 is configured to receive the control signal through the first driver board interface, and output a conversion signal after performing digital-to-analog or analog-to-digital conversion on the control signal. The light source driver unit 81 is configured to receive the conversion signal through the constant current board interface 72 to drive the laser tube 82 to perform corresponding display, such as lighting or extinguishing the laser tube 82, or lighting the laser tube 82 at a designated position, or extinguishing the laser tube 82 at a designated position, or controlling the laser tube 82 continues to be displayed with the specified brightness, etc. Content of the corresponding display of the laser tube 82 can be selected according to actual needs, which is not limited to the foregoing manners.

The control signal is received through the driver board interface 71, and the conversion signal is output after the digital-to-analog or analog-to-digital conversion is performed on the control signal. The light source driver unit 81 is configured to receive the conversion signal through the constant current board interface 73 to drive the laser tube 82 for corresponding display.

Specifically, the control signal generated by the master control unit 10 is used to control the working state of the laser tube 82, such as the lighting, extinguishing, and light output intensity of the laser tube 82, or used to control the laser tube 82 at a designated position to start or stop working.

In an embodiment, the master control board is also provided with the interface unit 12 as above mentioned. The master control unit is configured to acquire the control information of the laser tube 82 through the interface unit 12, and generate the control signal according to the control information of the laser tube 82. The interface unit 12 is configured to communicate with the operator control unit. The operator control unit is configured to monitor the state of the laser tube 82 and transmit the control information of the laser tube 82.

In addition, the first driver board interface and the second driver board interface may be connected in a tree-type connection, a star-type connection or a chain-type connection.

In this embodiment, the above-mentioned laser driver unit 15 may include a laser driver interface, through which the laser tube 82 is connected to the laser driver unit 15.

In an embodiment, the master control unit 10 may include a laser driver module, and the laser driver module is configured to output the control signal. With the above structure, the laser driver module is integrated into the master control unit 10, which can save space and reduce wiring complexity.

In an embodiment, the aforementioned control unit includes a touch control module 30, a wireless module 31 and a touch interface 32. The touch interface 32 is connected to the interface unit 12, the touch control module 30 is connected to the touch interface 32, and the wireless module 31 is connected to the master control unit 10.

The touch control module 30 includes, but is not limited to, a touch-sensitive screen, which is mainly used to receive related information of the laser tube 82 such as light energy, laser light source driving current, and light source temperature. The state of the laser tube 82 can also be controlled or displayed through the touch-sensitive screen. An input information of the touch control module 30 is transmitted to the interface unit 12 of the master control board through the touch interface 32, and then transmitted to the master control unit 10 of the master control board. The wireless module 31 is connected with an external vibrating screen system to realize data transmission and communication. Various information of the vibrating screen system can be transmitted to the master control unit 10 through the wireless module 31. Obviously, the information that needs to be displayed can also be output as a display signal by the master control board, and then displayed on the vibrating screen system via the wireless module 31.

In this embodiment, the wireless module 31 includes but is not limited to a WIFI module.

In an embodiment, the above-mentioned laser driver unit 15 is also connected to a control board interface 61, and the control board interface 61 is connected with a temperature control device 60. The temperature control device 60 is connected to the laser driver unit 15 through the control board interface 61, and temperature information of each laser tube 82 is acquired through the laser driver unit 15. If the temperature of the laser tube 82 exceeds a threshold, then the laser tube 82 is controlled to stop working.

In addition, the temperature control device 60 is also connected to the second driver board interface 72, and the temperature control device 60 communicates with the driver control unit 70 through the second driver board interface 72.

In an embodiment, the temperature control device 60, by communicating with the driver control unit 70, can acquire a connection position of the laser tube 82, a light-emitting color corresponding to the laser tube 82, and the temperature information of the laser tube 82. By acquiring the light-emitting color of the laser tube 82 at each position, it can be determined whether an installation of the laser tube 82 is correct. In an example, a preset information of the laser tubes 82 in the temperature control device 60 is RRGGBB, that is, the laser tubes 82 have a setting sequence of a laser tube 82 emitting laser light of red, a laser tube 82 emitting laser light of red, a laser tube 82 emitting laser light of green, a laser tube 82 emitting laser light of green, a laser tube 82 emitting laser light of blue and a laser tube 82 emitting laser light of blue. If it is detected that the setting sequence of the laser tubes 82 is not consistent with this, an alarm message may be sent to the master control single source 10. In another example, the preset information of the laser tube 82 in the temperature control device 60 is RRFGBB, that is, the laser tubes 82 have a setting sequence of a laser tube 82 emitting laser light of red, a laser tube 82 emitting laser light of red, and a floating (that is, no the laser tube 82 is set here), a laser tube 82 emitting laser light of green, a laser tube 82 emitting laser light of blue and a laser tube 82 emitting laser light of blue. If it is detected that the setting sequence of the laser tubes 82 does not match this, an alarm message may be sent to the master control single source 10.

In an embodiment, the above-mentioned master control board is provided with a cooling control unit 13, and a cooling unit 40 is provided to the cooling control unit 13.

The cooling mode of the aforementioned cooling unit 40 includes, but is not limited to, water cooling, air cooling or a cooling tube, that is configured to cool the laser tube 82. The cooling control unit 13 may include a cooling control interface.

In an embodiment, the temperature control device 60 can also be configured to acquire temperature of other components, such as temperature of the cooling water in the cooling unit 40, or ambient temperature inside a projection driver unit 14, or temperature near the control board, etc. If the preset value is exceeded, the laser light source is controlled to stop working.

In an embodiment, the above-mentioned master control board is provided with a projection driver unit 14, and a projection device 50 is connected to the projection driver unit 14. The above-mentioned projection device 50 includes, but is not limited to, a projector. The projection driver unit 14 is connected to an external projection device 50, and the projection device 50 acquires required information through the master control unit 10, such as the on-off state of the light source, the power supply current of the laser tube 82, and the like. Alternatively, the projection driver unit 14 may communicate with the external projection device 50 through a ballast interface of the external projection device 50. Specifically, the projection device 50 may stop the projection when the information that the light source has been turned on is not acquired.

In this embodiment, the above-mentioned projection driver unit 14 includes a projection driver interface, and the projection driver interface is connected to a projector integrated cinema processor (ICP) board of the projection device 50.

In one embodiment, a power connection unit 11 connected to the master control unit 10 is provided on the above-mentioned master control board. A power supply unit is connected to the power connection unit 11, and the power supply unit supplies power to the master control unit 10 through the power connection unit 11. In this embodiment, the above-mentioned power connection unit 11 includes, but is not limited to, a power connection interface.

In an embodiment, the above-mentioned power supply unit includes a main power supply module 20 and an auxiliary power supply module 21, and the main power supply module 20 and the auxiliary power supply module 21 are respectively connected to the power connection unit 11.

In this embodiment, the above-mentioned main power supply module 20 includes but is not limited to a 24V main power supply, and the auxiliary power supply module 21 includes but is not limited to a 12V auxiliary power supply. Due to power supply demand of the projection device 50, the main and auxiliary power supplies are set to meet the demand of the system itself.

Obviously, in other embodiments, the main power supply module 20 and the auxiliary power supply module 21 are connected to the power connection unit 11 through a switching element. The switching element includes but is not limited to a field effect transistor. The switching element is controlled by the master control unit 10 to determine whether the main power supply module 20 and the auxiliary power supply module 21 are selected to supply power or not.

In other embodiments, a switching element is connected between the main power module 20 and the auxiliary power module 21, and the switching element is configured to switch between the main power module 20 and the auxiliary power module 21 for power supply.

In other embodiments, both the main power module 20 and the auxiliary power module 21 can participate in power supply.

In an embodiment, a sensor connection unit 16 is provided on the above-mentioned master control board, and a sensor 90 is connected to the sensor connection unit 16.

In this embodiment, the sensor 90 includes a color sensor 90. The color sensor 90 may be configured for white balance detection and adjustment. The method of white balance detection can be selected according to actual needs. In an example, an actual value can be compared with a preset value, and when the actual value deviates far, it can be adjusted to the preset value. Or, a standard value is calculated according to the practical environment on site, and the actual value is adjusted to the preset value.

The above laser light source control system is provided with a master control board, a driver control board, a light source driver board 80 and an operator control unit. The master control board is provided with a master control unit 10 for controlling components other than digital-to-analog or analog-to-digital conversion of signals and a driving current that drivers the laser tube 82. The driver control unit 70 in the driver control board is responsible for AD or DA conversion, and transmits information of the drive current to the master control unit 10 of the master control board. The light source driver unit 81 of the light source driver board 80 is configured to generate the driving current for driving the laser tube 82. Such that the calculation pressure of the master control board and the wiring complexity are reduced, which is applicable for special scenarios.

In an embodiment, it is also provided a control method of the laser light source control system, which includes: inputting, by an operator control unit, relevant information of a laser tube 82; receiving, by a master control unit 10, the relevant information of the laser tube 82 through an interface unit 12 and outputting a control signal through a laser driver unit 15; receiving, by a driver control unit 70, the control signal through a driver board interface 71, and outputting a conversion signal after the digital-to-analog or analog-to-digital conversion is performed on the control signal; and receiving, by a light source driver unit 81, the conversion signal through a constant current board interface 73 to drive the laser tube 82 to perform corresponding display.

It should be noted that the various units or modules mentioned in the above embodiments can be selected according to actual needs, so as to realize the functions required by each unit or module. For example, the master control unit 10 may be a Micro Control Unit (MCU), a central processing unit or a single-chip computer, etc., and the laser driver unit may be a MAX series driver chip, the same MCU as the master control unit 10, or other types of driver chip, or it may be implemented by a circuit structure integrated in the master control unit 10. Exemplarily, the driver control unit may include a MAX series driver chip, a ST series driver chip, a DA conversion circuit or an AD conversion circuit. Temperature control device may include a MAX series driver chip, a ST series driver chip or a central processing unit. The projection driver unit may include a CPU (Central Processing Unit) or a single-chip computer. It should be noted that those skilled in the art can clearly understand that the specific implementation of the control method of the laser light source control system can refer to the corresponding description in the foregoing laser light source control system embodiment. For the convenience and conciseness of the description, it will not be repeat here.

The above only uses embodiments to further illustrate the technical content of the present application, so as to make it easier for readers to understand, but it does not mean that the implementation of the present application is limited to this. Any technical extension or re-creation made on the basis of the present application shall be subject to the protection of the present application. The protection scope of the present application is subject to the claims.

1. A laser light source control system, comprising:
a master control board provided with a master control unit and a laser driver unit, wherein the master control unit is configured to output a control signal through the laser driver unit;
a driver control board provided with a driver control unit, a first driver board interface and a constant current board interface, wherein the driver control unit is configured to receive the control signal through the first driver board interface, and output a conversion signal after performing digital-to-analog or analog-to-digital conversion on the control signal;
a light source driver board provided with a light source driver unit, wherein the light source driver unit is configured to receive the conversion signal through the constant current board interface to drive the laser tube to perform corresponding display; and
an operator control unit configured to monitor a state of the laser tube and acquire control information of the laser tube;
wherein a plurality of the driver control boards are connected through the first driver board interface, and the first driver board interface is connected with a second driver board interface, and the master control board is connected to the driver control board through the second driver board interface.

2. The laser light source control system according to claim 1, wherein the master control board is further provided with an interface unit, the master control unit is configured to acquire control information of the laser tube through the interface unit, and generate the control signal according to the control information of the laser tube; and wherein the interface unit is configured to communicate with the operator control unit, and the operator control unit is configured to monitor the state of the laser tube and transmit the control information of the laser tube.

3. The laser light source control system according to claim 1, wherein the first driver board interface and the second driver board interface are connected in a tree-type connection, a star-type connection or a chain-type connection.

4. The laser light source control system according to claim 1, wherein the operator control unit comprises a touch module, a wireless module, and a touch interface; and the touch interface is connected to the interface unit, the touch module is connected to the touch interface, and the wireless module is connected to the master control unit.

5. The laser light source control system according to claim 1, wherein the laser driver unit is further connected to a control board interface, the control board interface is connected to a temperature control device, and the temperature control device is connected to the laser driver unit through the control board interface and configured to acquire temperature information of each laser tube through the laser driver unit; and when the temperature of the laser tube exceeds a threshold, the laser tube is controlled to stop working.

6. The laser light source control system according to claim 5, wherein the temperature control device is further connected to a second driver board interface, and the temperature control device communicates with the driver control unit through the second driver board interface.

7. The laser light source control system according to claim 1, wherein a cooling control unit is provided on the master control board, and a cooling unit is connected to the cooling control unit.

8. The laser light source control system according to claim 1, wherein a power connection unit connected to the master control unit is connected to the master control board, and a power supply unit is connected to the power connection unit, wherein the power supply unit comprises a main power supply module and an auxiliary power supply module, and the main power supply module and the auxiliary power supply module are respectively connected to the power connection unit.

9. The laser light source control system according to claim 1, wherein a sensor connection unit is provided on the master control board, and a sensor is connected to the sensor connection unit; and wherein the sensor comprises a color sensor.

10. A control method of the laser light source control system, comprising:
inputting, by an operator control unit, relevant information of a laser tube;
receiving, by a master control unit, the relevant information of the laser tube through an interface unit, and outputting a control signal through a laser driver unit;
receiving, by a driver control unit, the control signal through a driver board interface, and outputting a conversion signal after performing digital-to-analog or analog-to-digital conversion on the control signal; and
receiving, by a light source driver unit, the conversion signal through the constant current board interface to drive the laser tube to perform corresponding display.
